(19) United States
(12) Patent Application Publication
(10) Pub. No.: US 2025/0234689 A1
(43) Pub. Date: Jul. 17, 2025

(54) LED PACKAGE STRUCTURE AND DISPLAY DEVICE

(71) Applicant: ADVANCED OPTOELETRONIC TECHNOLOGY, INC., Hsinchu County (TW)

(72) Inventors: CHUANG-YU HSIEH, Hsinchu (TW); Hao-Hsiang Hsieh, Hsinchu (TW); Hsin-Ting Hung, Hsinchu (TW)

(21) Appl. No.: 18/738,006

(22) Filed: Jun. 8, 2024

(30) Foreign Application Priority Data
Jan. 12, 2024 (CN) 202410047638.4

(51) Int. Cl. H01L 33/60; H01L 25/075; H01L 33/62

(52) U.S. Cl. CPC H10H 20/856; H01L 25/0753; H10H 20/857

(57) ABSTRACT

A LED package structure is provided, comprising a light-emitting layer, a first medium layer, a second medium layer, a third medium layer and a reflective layer. A first surface of the first medium layer is attached to the light-emitting layer. A second surface of the first medium layer is attached to the third surface of the second medium layer, a refractive index of the second surface is larger than a refractive index of the third surface. A fourth surface of the second medium layer is attached to the fifth surface of the third medium layer, a refractive index of the fourth surface is larger than a refractive index of the fifth surface. The reflective layer is provided on a side of the third medium layer away from the second medium layer. A display device is also provided.

### FIELD

The present disclosure relates to field of semiconductor lighting technology, particularly to a LED package structure, and a display device.

### BACKGROUND

When a LED chip emitted light, the light reaches the air and will have total reflection on highly reflective material of an existing LED package structure, most light emitted by the LED chip cannot be transferred out of the existing LED package structure, light output efficiency of the existing LED package structure is very low. In prior art, package fluorescent adhesive is usually arranged between the LED chip and the highly reflective material to improve the light output efficiency, but light can be absorbed by the high-reflective material layer and the package fluorescent adhesive, light efficiency of the existing LED package structure is still low.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 illustrates a structure diagram of a LED package structure in the prior art.

FIG. 2 illustrates a structure diagram of the LED package structure in an embodiment.

FIG. 3 illustrates a structure diagram of the LED package structure in an embodiment.

FIG. 4 illustrates a structure diagram of the LED package structure in an embodiment.

FIG. 5 illustrates a diagram of a display device in an embodiment.

### DETAILED DESCRIPTION

In order to make the above-mentioned objects, features and advantages of the present application more obvious, a detailed description of specific embodiments of the present application will be described in detail with reference to the accompanying drawings. A number of details are set forth in the following description so as to fully understand the present application. However, the present application can be implemented in many other ways different from those described herein, and those skilled in the art can make similar improvements without violating the contents of the present application. Therefore, the present application is not to be considered as limiting the scope of the embodiments described herein.

Several definitions that apply throughout this disclosure will now be presented.

The term “coupled” is defined as coupled, whether directly or indirectly through intervening components, and is not necessarily limited to physical connections. The connection may be such that the objects are permanently coupled or releasably coupled. The term “substantially” is defined to be essentially conforming to the particular dimension, shape, or other feature that the term modifies, such that the component need not have that exact feature. The term “comprising,” when utilized, means “including, but not necessarily limited to”; it specifically indicates open-ended inclusion or membership in the so-described combination, group, series, and the like.

Unless otherwise defined, all technical and scientific terms used herein have the same meaning as commonly understood by one skilled in the art. The terms used in a specification of the present application herein are only for describing specific embodiments and are not intended to limit the present application. The terms “and/or” used herein comprises any and all combinations of one or more of associated listed items.

Some embodiments of the present application are described in detail. In the case of no conflict, the following embodiments and the features in the embodiments can be combined with each other.

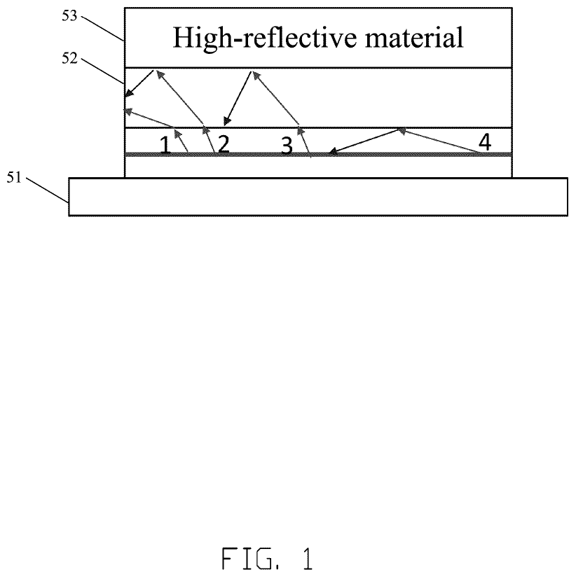

Referring to FIG. 1, in the prior art, an existing LED package structure includes a light-emitting layer 51, package fluorescent adhesive 52, and a high-reflective material layer 53. The package fluorescent adhesive 52 is arranged between the light-emitting layer 51 and the high-reflective material layer 53. A path 1, a path 2, a path 3 and a path 4 are light paths. The lights in the path 1 and the path 2 are reflected by the high-reflective material layer 53 and be emitted out from a side of the package fluorescent adhesive 52. The lights in the path 3 and the path 4 are absorbed by the high-reflective material layer 53 and the package fluorescent adhesive 52, and the lights in the path 3 and the path 4 cannot be emitted out from a side of the package fluorescent adhesive 52, therefore the light output efficiency of the existing LED package structure is low.

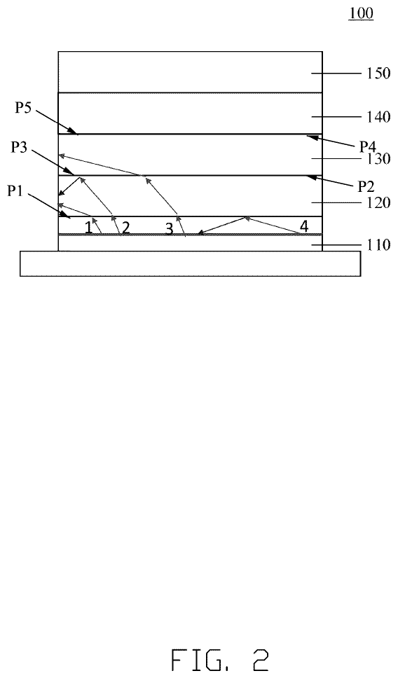

Referring to FIG. 2, one embodiment of the present application discloses a LED package structure 100. The LED package structure 100 includes a light-emitting layer 110, a first medium layer 120, a second medium layer 130, a third medium layer 140, and a reflective layer 150. The first medium layer 120 is arranged on an upper side of the light-emitting layer 110. The second medium layer 130 is arranged on a side of the first medium layer 120 away from the light-emitting layer 110. The third medium layer 140 is arranged on a side of the second medium layer 130 away from the first medium layer 120. The reflective layer 150 is arranged on a side of the third medium layer 140 away from the second medium layer 130.

A first surface P1 is provided on a side of the first medium layer 120 close to the light-emitting layer 110, the first surface P1 is attached to the light-emitting layer 110. A second surface P2 is provided on a side of the first medium layer 120 away from the light-emitting layer 110, a third surface P3 is provided on a side of the second medium layer 130 close to the first medium layer 120. The second surface P2 is attached to the third surface P3, a refractive index of the second surface P2 is larger than a refractive index of the third surface P3. A fourth surface P4 is provided on the side of the second medium layer 130 away from the first medium layer 120, a fifth surface P5 is provided on the side of the third medium layer 140 close to the second medium layer 130, the fourth surface P4 is attached to the fifth surface P5, a refractive index of the fourth surface P4 is larger than a refractive index of the fifth surface P5.

In one embodiment, the light-emitting layer 110 includes one or more LED chip 111. The LED chip 111 emits light to the first medium layer 120, the second medium layer 130, the third medium layer 140 and the reflective layer 150. The reflective layer 150 is made of white glue or metal material with high reflectivity. Based on a principle of total reflection of the light, if the light is emitted from high refraction coefficient of material to low refraction coefficient of the material, when an incidence Angle of the light is larger than or equal to a critical Angle of the light, total reflection of the light is produced.

In one embodiment, when the light emitted by the light-emitting layer 110 is refracted by the first medium layer 120 to reach the second medium layer 130, the light along the path 3 is which the incidence Angle of the light is less than the critical Angle of the light, the light is refracted by the second medium layer 130 to emit out from a side of the second medium layer 130.

In other embodiments, the light passed through the second medium layer 130 to the third medium layer 140, and the light is emitted out from a side of the third medium layer 140. When the light along the path 1 or path 2 is which the incidence Angle of the light is larger than or equal to the critical Angle of the light, the light is fully reflected on the third surface P3, and the light can be emitted out from a side of the first medium layer 120.

In one embodiment, when the incidence Angle of the light is less than the critical Angle of the light, the light from the fourth surface P4 to the fifth surface P5 is refracted from the third medium layer 140. In other embodiments, the light passes through the third medium layer 140 to the reflective layer 150, and the light is reflected from the side of the third medium layer 140. When the incidence Angle of the light is larger than or equal to the critical Angle of the light, the light is fully reflected on the fifth surface P5, and the light can be emitted out from the side of the second medium layer 130. The light paths are increased, and the lights are emitted evenly out from four sides of each medium layer.

Each of the first medium layer 120, the second medium layer 130, and the third medium layer 140 includes one or more layer of transparent refracting material. In one embodiment, the first medium layer 120, the second medium layer 130 and the third medium layer 140 can adopt one layer of the transparent refracting material, and a refractive index of the first medium layer 120, a refractive index of the second medium layer 130, and a refractive index of the third medium layer 140 decrease gradually (the refractive index of the first medium layer 120>the refractive index of the second medium layer 130>the refractive index of the third medium layer 140). In other embodiments, the first medium layer 120 can include multiple layers of transparent refracting material with different refractive index.

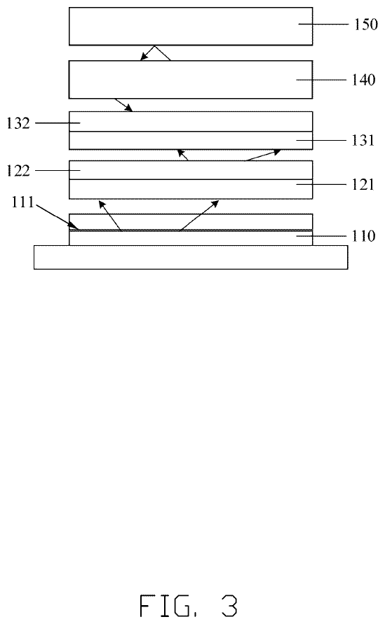

Referring to FIG. 3, the first medium layer 120 includes a first refractor layer 121 and a second refractor layer 122. The first refractor layer 121 is close to the light-emitting layer 110, the second refractor layer 122 is close to the second medium layer 130. The first surface P1 is provided on a side of the first refractor layer 121 away from the second refractor layer 122. The second medium layer 130 includes a third refractor layer 131 and a fourth refractor layer 132. The third refractor layer 131 is close to the first medium layer 120, the fourth refractor layer 132 is close to the third medium layer 140. The third surface P3 is provided on a side of the third refractor layer 131 away from the fourth refractor layer 132, the fourth surface P4 is provided on a side of the fourth refractor layer 132 away from the third refractor layer 131. A refractive index of the second refractor layer 122 is larger than a refractive index of the third refractor layer 131 (the refractive index of the second refractor layer 122>the refractive index of the third refractor layer 131).

Material of the first refractor layer 121, the second refractor layer 122, the third refractor layer 131 and the fourth refractor layer 132 can be transparent glue or dielectric material. A refractive index of the first refractor layer 121, the refractive index of the second refractor layer 122, the refractive index of the third refractor layer 131 and a refractive index of the fourth refractor layer 132 can decrease in sequence (the refractive index of the first refractor layer 121>the refractive index of the second refractor layer 122>the refractive index of the third refractor layer 131>the refractive index of the fourth refractor layer 132). In other embodiments, the refractive indexes of the first refractor layer 121, the second refractor layer 122, the third refractor layer 131 and the fourth refractor layer 132 can be set alternately high refractive index and low refractive index (the refractive index of the first refractor layer 121<the refractive index of the second refractor layer 122<the refractive index of the third refractor layer 131<the refractive index of the fourth refractor layer 132).

In one embodiment, the refractive index of the second refractor layer 122 is larger than the refractive index of the first refractor layer 121 (the refractive index of the second refractor layer 122>the refractive index of the first refractor layer 121). The refractive index of the fourth refractor layer 132 is larger than the refractive index of the third refractor layer 131 (the refractive index of the fourth refractor layer 132>the refractive index of the third refractor layer 131).

In other embodiments, the refractive index of the second refractor layer 122 is larger than the refractive index of the first refractor layer 121 (the refractive index of the second refractor layer 122>the refractive index of the first refractor layer 121). The refractive index of the fourth refractor layer 132 is less than the refractive index of the third refractor layer 131 (the refractive index of the fourth refractor layer 132<the refractive index of the third refractor layer 131). The light can fully be reflected in the first medium layer 120 and the second medium layer 130, angle difference is generated through multi-layer refracting material to increase the light efficiency.

In one embodiment, the refractive index of the first refractor layer 121 is larger than the refractive index of the second refractor layer 122 (the refractive index of the first refractor layer 121>the refractive index of the second refractor layer 122), the refractive index of the third refractor layer 131 is less than the refractive index of the fourth refractor layer 132 (the refractive index of the third refractor layer 131<the refractive index of the fourth refractor layer 132). The light can fully be reflected in the first medium layer 120 and the second medium layer 130, the angle difference is generated through multi-layer refracting material to increase the light efficiency.

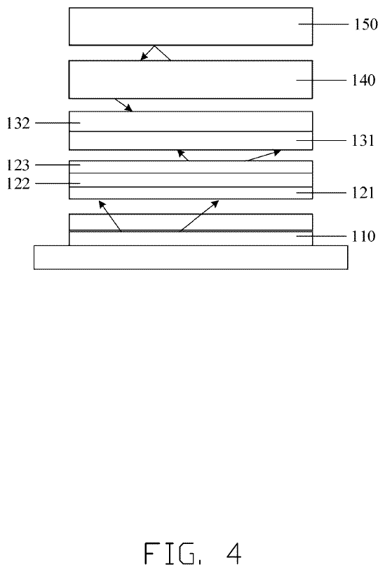

Referring to FIG. 4, the first medium layer 120 also includes a fifth refractor layer 123. The fifth refractor layer 123 is arranged between the second refractor layer 122 and the third refractor layer 131, the second surface P2 is provided on a side of the fifth refractor layer 123 away from the first refractor layer 121. The refractive index of the first refractor layer 121 is larger than the refractive index of the second refractor layer 122, the refractive index of the second refractor layer 122 is less than a refractive index of the fifth refractor layer 123, the refractive index of the fifth refractor layer 123 is larger than the refractive index of the third refractor layer 131 (the refractive index of the first refractor layer 121>the refractive index of the second refractor layer 122, the refractive index of the second refractor layer 122<the refractive index of the fifth refractor layer 123>the refractive index of the third refractor layer 131).

In one embodiment, after the light is emitted out from the light-emitting layer 110, the light can be reflected or refracted between the first refractor layer 121 and the second refractor layer 122 in the first medium layer 120, and the refracted light can produce total reflection or refraction again through the fifth refractor layer 123 and the third refractor layer 131. The light can be emitted out from the side of the second medium layer 130 or the side of the third medium layer 140. The light paths of the light are increased, the light efficiency is improved.

In other embodiments, a number of refracting material layers in the first medium layer 120 can also be adjusted according to actual needs, and a number of refracting material layers in the second medium layer 130 can also be adjusted according to actual needs. When the third medium layer 140 includes multiple layers of transparent material, a structure of the third medium layer 140 can be set according to the first medium layer 120 or the second medium layer 130.

The first medium layer 120, the second medium layer 130 and the third medium layer 140 are arranged on emission direction of the light-emitting layer 110. The refractive indexes of the first medium layer 120, the second medium layer 130 and the third medium layer 140 are set from the high refractive index to the low refractive index, the light can be fully reflected or refracted in the second medium layer 130 and the third medium layer 140. The light paths of the light are increased, the light efficiency is improved.

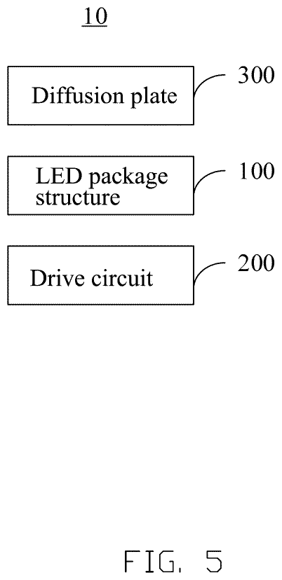

Referring to FIG. 5, one embodiment of the present application discloses a display device 10. The display device 10 includes the LED package structure 100, a drive circuit 200, and a diffusion plate 300. The drive circuit 200 is coupled with the LED package structure 100, the drive circuit 200 is configured to drive the LED package structure 200 to emit the light. The diffusion plate 300 is arranged on a side of the LED package structure 100, the diffusion plate 300 is configured to adjust propagation direction of the light.

In one embodiment, the display device 10 also includes a circuit board. The drive circuit 200 and the LED package structure 100 can be installed on the circuit board. The drive circuit 200 drives the light-emitting layer 110 in the LED package structure 100 to emit light through an output drive signal. The diffusion plate 300 can interfere with the light emitted by the LED package structure 100, the light refracts, reflects, and scatters in different directions to change the paths of lights. Full dispersion of the incident light is achieved to produce optical diffusion effect, and the brightness of the display device is improved. The LED package structure 100 can increase the light paths, improve the light efficiency, and have a uniform light effect, a thickness of the diffusion plate 300 or a number of the diffusion plate 300 are reduced, and then a thickness of the display device 10 is also reduced.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A light emitting diode (LED) package structure comprising:
a light-emitting layer;
a first medium layer arranged on a side of the light-emitting layer, wherein a first surface is provided on a side of the first medium layer close to the light-emitting layer, the first surface is attached to the light-emitting layer;
a second medium layer arranged on a side of the first medium layer away from the light-emitting layer, wherein a second surface is provided on a side of the first medium layer away from the light-emitting layer, a third surface is provided on a side of the second medium layer close to the first medium layer, the second surface is attached to the third surface, a refractive index of the second surface is larger than a refractive index of the third surface;
a third medium layer arranged on a side of the second medium layer away from the first medium layer, wherein a fourth surface is provided on the side of the second medium layer away from the first medium layer, a fifth surface is provided on a side of the third medium layer close to the second medium layer, the fourth surface is attached to the fifth surface, a refractive index of the fourth surface is larger than a refractive index of the fifth surface; and
a reflective layer arranged on a side of the third medium layer away from the second medium layer.

2. The LED package structure as claimed in claim 1, wherein the first medium layer comprises a first refractor layer and a second refractor layer, the first refractor layer is close to the light-emitting layer, the second refractor layer is close to the second medium layer, the first surface is provided on a side of the first refractor layer away from the second refractor layer; the second medium layer comprises a third refractor layer and a fourth refractor layer, the third refractor layer is close to the first medium layer, the fourth refractor layer is close to the third medium layer, the third surface is provided on a side of the third refractor layer away from the fourth refractor layer, the fourth surface is provided on a side of the fourth refractor layer away from the third refractor layer; a refractive index of the second refractor layer is larger than a refractive index of the third refractor layer.

3. The LED package structure as claimed in claim 2, wherein the refractive index of the second refractor layer is larger than a refractive index of the first refractor layer.

4. The LED package structure as claimed in claim 3, wherein a refractive index of the fourth refractor layer is larger than the refractive index of the third refractor layer.

5. The LED package structure as claimed in claim 3, wherein a refractive index of the fourth refractor layer is less than the refractive index of the third refractor layer.

6. The LED package structure as claimed in claim 2, wherein a refractive index of the first refractor layer is larger than the refractive index of the second refractor layer, a refractive index of the fourth refractor layer is larger than the refractive index of the third refractor layer.

7. The LED package structure as claimed in claim 2, wherein the first medium layer further comprises a fifth refractor layer, the fifth refractor layer is arranged between the second refractor layer and the third refractor layer, the second surface is provided on a side of the fifth refractor layer away from the first refractor layer; a refractive index of the first refractor layer is larger than the refractive index of the second refractor layer, the refractive index of the second refractor layer is less than a refractive index of the fifth refractor layer, the refractive index of the fifth refractor layer is larger than the refractive index of the third refractor layer.

8. The LED package structure as claimed in claim 1, wherein the light-emitting layer comprises one or more LED chip, the LED chip emits light to the first medium layer, the second medium layer, the third medium layer and the reflective layer.

9. A display device comprising:
a light-emitting layer;
a first medium layer arranged on a side of the light-emitting layer, wherein a first surface is provided on a side of the first medium layer close to the light-emitting layer, the first surface is attached to the light-emitting layer;
a second medium layer arranged on a side of the first medium layer away from the light-emitting layer, wherein a second surface is provided on a side of the first medium layer away from the light-emitting layer, a third surface is provided on a side of the second medium layer close to the first medium layer, the second surface is attached to the third surface, a refractive index of the second surface is larger than a refractive index of the third surface;
a third medium layer arranged on a side of the second medium layer away from the first medium layer, wherein a fourth surface is provided on the side of the second medium layer away from the first medium layer, a fifth surface is provided on a side of the third medium layer close to the second medium layer, the fourth surface is attached to the fifth surface, a refractive index of the fourth surface is larger than a refractive index of the fifth surface; and
a reflective layer arranged on a side of the third medium layer away from the second medium layer.

10. The display device as claimed in claim 9, wherein the first medium layer comprises a first refractor layer and a second refractor layer, the first refractor layer is close to the light-emitting layer, the second refractor layer is close to the second medium layer, the first surface is provided on a side of the first refractor layer away from the second refractor layer; the second medium layer comprises a third refractor layer and a fourth refractor layer, the third refractor layer is close to the first medium layer, the fourth refractor layer is close to the third medium layer, the third surface is provided on a side of the third refractor layer away from the fourth refractor layer, the fourth surface is provided on a side of the fourth refractor layer away from the third refractor layer; a refractive index of the second refractor layer is larger than a refractive index of the third refractor layer.

11. The display device as claimed in claim 10, wherein the refractive index of the second refractor layer is larger than a refractive index of the first refractor layer.

12. The display device as claimed in claim 11, wherein a refractive index of the fourth refractor layer is larger than the refractive index of the third refractor layer.

13. The display device as claimed in claim 11, wherein a refractive index of the fourth refractor layer is less than the refractive index of the third refractor layer.

14. The display device as claimed in claim 10, wherein a refractive index of the first refractor layer is larger than the refractive index of the second refractor layer, a refractive index of the fourth refractor layer is larger than the refractive index of the third refractor layer.

15. The display device as claimed in claim 10, wherein the first medium layer further comprises a fifth refractor layer, the fifth refractor layer is arranged between the second refractor layer and the third refractor layer, the second surface is provided on a side of the fifth refractor layer away from the first refractor layer; a refractive index of the first refractor layer is larger than the refractive index of the second refractor layer, the refractive index of the second refractor layer is less than a refractive index of the fifth refractor layer, the refractive index of the fifth refractor layer is larger than the refractive index of the third refractor layer.

16. The display device as claimed in claim 9, wherein the light-emitting layer comprises one or more LED chip, the one or more LED chip emits light to the first medium layer, the second medium layer, the third medium layer and the reflective layer.

17. The display device as claimed in claim 9, wherein the display device further comprises a drive circuit and a diffusion plate, the drive circuit is coupled with the LED package structure, the drive circuit is configured to drive the LED package structure to emit light, the diffusion plate is arranged on a side of the LED package structure, the diffusion plate is configured to adjust propagation direction of the light.
